(19) United States
(12) Patent Application Publication
(10) Pub. No.: US 2024/0084446 A1
(43) Pub. Date: Mar. 14, 2024

(54) REACTION CHAMBER COMPONENT, DEPOSITION APPARATUS PROVIDED WITH SUCH COMPONENT AND METHOD OF PROTECTING SUCH COMPONENT

(71) Applicant: ASM IP Holding, B.V., Almere (NL)

(72) Inventors: Iordan Iordanov, Tempe, AZ (US); Christiaan Werkhoven, Sonoita, AZ (US); Loke Yuen Wong, Singapore (SG); Ivo Johannes Raaijmakers, Amersfoort (NL); Osama Khalil, Chandler, AZ (US)

(21) Appl. No.: 18/465,787

(22) Filed: Sep. 12, 2023

Related U.S. Application Data
(60) Provisional application No. 63/375,560, filed on Sep. 14, 2022.

(51) Int. Cl. C23C 16/40; C23C 16/32; C23C 16/34; C23C 16/455; C23C 16/458

(52) U.S. Cl. CPC C23C 16/40; C23C 16/325; C23C 16/34; C23C 16/45553; C23C 16/458

(57) ABSTRACT

A reaction chamber component for use in a deposition apparatus for depositing a layer of a first material on a substrate is provided. The component may have a base material being partially coated with a liner of the first material. The component may have a protective layer of a second material different than the first material on top of the liner of the first material to protect the component. This may be useful during a removal process for removing a parasitic coating of the same first material deposited during use of the reaction chamber component.

### CROSS-REFERENCE TO RELATED APPLICATION(S)

This application claims the benefit of U.S. Provisional Application 63/375,560 filed on Sep. 14, 2022, the entire contents of which are incorporated herein by reference.

### TECHNICAL FIELD

The disclosure relates to a reaction chamber component constructed and arranged for use in a deposition apparatus for depositing a layer of a first material on a substrate. The component may comprise a base material being at least partially coated with a liner of the first material.

### BACKGROUND OF THE DISCLOSURE

The reaction chamber component may be used in a deposition apparatus for depositing a layer of a first material on a substrate. The component may be a (part) of a substrate support for holding the substrate in the reaction chamber, a reaction chamber wall for forming the reaction chamber, a divider for dividing the reaction chamber, an injector for providing gasses in the reaction chamber, or an exhaust for removing gas from the reaction chamber.

The first material may for example be silicon carbide. During use the reaction chamber component may receive a parasitic coating of the same first material. The parasitic coating may accumulate during multiple deposition runs on the reaction chamber component and the accumulated layer may peel off during heating—cooling cycles and flakes of the layer may drop on the substrates which may be unwanted.

It may therefore be necessary to remove the parasitic coating of the first material on the reaction chamber components. Removal of this parasitic coating, sometimes called cleaning or etching, may be difficult since the component may be coated with a liner of the same first material. The base material may be coated with the liner to avoid that the base material may be damaged due to shipping and installation in the reaction chamber, or by any of the processes utilized in the reactor chamber or to avoid transfer of impurities from the base material into the substrate during deposition of the first material. The integrity of the liner may therefore be of importance for the quality of the first material deposited on the substrate.

Any cleaning of the component may therefore not only remove the parasitic coating as intended but may also partially remove the liner unintentionally. The time needed to remove the parasitic coating depends on the thickness of the parasitic coating and details of the cleaning process, the former may vary substantially across the surface of a component or from component to component. That may lead to a complete removal of the liner. Where the liner is removed the base material may be exposed and damaged by the cleaning process which may be unwanted. It may be difficult to find a removal process that is selectively removing the parasitic coating of the first material and not removing the liner of the same first material of the reaction chamber component.

Accordingly, there may be need for a reaction chamber component that may be better protected during the removal process.

### SUMMARY OF THE DISCLOSURE

According to an example, there may be provided a reaction chamber component for a reaction chamber for a deposition apparatus for depositing a layer of a first material on a substrate. The component may comprise a base material being at least partially coated with a liner of the first material. The component may be at least partially provided with a protective layer of a second material different than the first material on top of the liner of the first material to protect the component.

According to a further example, there may be provided a deposition apparatus for depositing a layer of a first material, such as silicon carbide, on a substrate. The apparatus may comprise a reaction chamber component comprising a base material being at least partially coated with a liner of the first material. The component may be at least partially provided with protective layer of a second material different than the first material on top of the liner of the first material to protect the component.

According to yet a further example, there may be provided a method of protecting a reaction chamber component for a reaction chamber of an apparatus for depositing a layer of a first material on a substrate. The component may be at least partially coated with a liner of the first material. The method comprises providing a protective layer of a second material different than the first material on top of the liner of the first material. The method may comprise removing the silicon carbide layer with a wet etch or a dry etch, and protecting the liner from the wet etch or the dry etch with the protective layer during the wet etch or dry etch.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

The invention will be better explained by the detailed description of the embodiments and from the drawings, which are meant to illustrate and not to limit the invention, and wherein:

FIG. 1 is a schematic cross-sectional view of a reaction chamber according to an embodiment;

FIG. 2 is a flow chart according to an embodiment to provide a protective layer on a component according to various embodiments;

FIG. 3 is a flow chart according to an embodiment to provide a sacrificial layer on a component which may be provided on top of a protective layer in accordance with FIG. 2; and,

FIG. 4 is a cross-sectional view on the layers, including the parasitic coating on a reaction chamber component according to an embodiment.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials that may be used, or upon which, a device, a circuit, or a film may be formed. The “substrate” may be continuous or non-continuous; rigid or flexible; solid or porous. The substrate may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example.

A continuous substrate may extend beyond the bounds of a reaction chamber where a deposition process occurs and may move through the process chamber such that the process continues until the end of the substrate is reached. A continuous substrate may be supplied from a continuous substrate feeding system allowing for manufacture and output of the continuous substrate in any appropriate form.

Non-limiting examples of a continuous substrate may include a sheet, a non-woven film, a roll, a foil, a web, a flexible material, a bundle of continuous filaments or fibers (i.e. ceramic fibers or polymer fibers). Continuous substrates may also comprise carriers or sheets upon which non-continuous substrates are mounted.

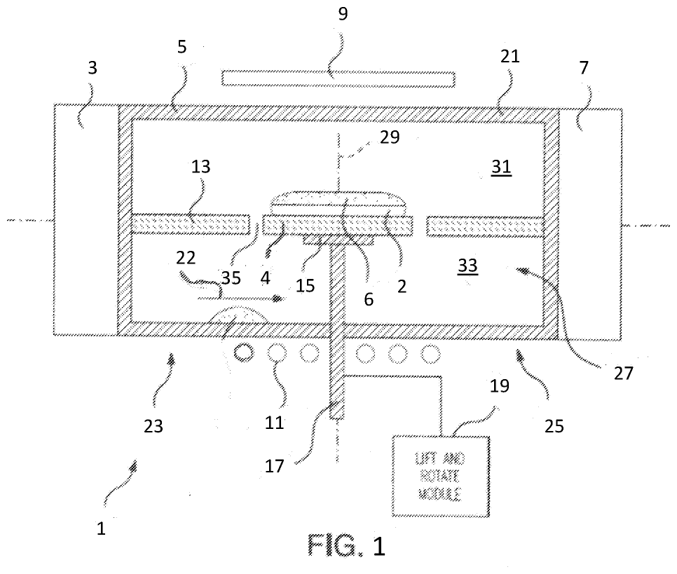

With reference to FIG. 1, a reaction chamber 1 is shown. The reaction chamber 1 may be constructed and arranged for use in a deposition apparatus for depositing a material layer 6 of a first material on a substrate 2. The material layer 6 of the first material to be deposited on the substrate 2 may for example be silicon carbide (SiC).

The reaction chamber 1 may include reaction chamber components such as an injector (e.g. injection flange 3), a substrate support 4, a reaction chamber wall 5, and an exhaust (e.g. exhaust flange 7). The reaction chamber 1 may also be provided with an upper lamp array 9 (or any other heating facility), and a lower lamp array 11 (or any other heating facility). The reaction chamber 1 may further comprise components, such as a divider 13 for dividing the reaction chamber and a support member 15 for supporting the substrate support 4. A shaft 17, and a lift and rotate module 19 may be provided to move the substrate support 4 in the reaction chamber 1. Although a particular arrangement of the reaction chamber 1 is shown and described herein, it is to be understood and appreciated that the chamber arrangements having other arrangement may also benefit from the present disclosure.

The reaction chamber wall 5 may be formed from a transparent material 21 and has an injection end 23 and a longitudinally opposite (relative to a general direction of fluid flow 22 through the reaction chamber 1) exhaust end 25. The reaction chamber 1 also has an interior 27, which is hollow. The injection flange 3 may be connected to the injection end 23 of the reaction chamber 1 and fluidly couples a gas delivery system to the interior 27 of the reaction chamber 1. The exhaust flange 7 may be connected to the exhaust end 25 of the reaction chamber 1 and is fluidly coupled to an interior 25 of the reaction chamber 1. In certain examples, the transparent material 21 forming the reaction chamber 1 may be ceramic material. Examples of suitable transparent materials include quartz. In case heating facilities are used that do not require transparency of the reactor chamber wall, other ceramic materials may be suitable, like aluminum oxide.

The upper lamp array 9 may be supported above the reaction chamber wall 5 and may be configured to heat the one or more substrates, e.g., the substrate 2 on the substrate support 4. In certain examples the upper lamp array 9 may include one or more linear lamp. The upper lamp array 9 may include a filament-type lamp or any other filament type heater. The upper lamp array 9 may include one or more linear lamp extending longitudinally above the reaction chamber wall 5 between the injection end 23 and the exhaust end 25 of the reaction chamber wall 5. In accordance with certain examples, the upper lamp array 9 may include a plurality of linear lamps. The plurality of linear lamps may be laterally spaced apart from one another between the longitudinally opposite injection end 23 and the exhaust end 25 of the reaction chamber 1. The plurality of linear lamps may extend laterally across the reaction chamber wall 5 between laterally opposite sides of the interior 27.

The lower lamp array 11 may be similar to the upper lamp array 9 and may be supported below the reaction chamber wall 5. In certain examples, the lower lamp array 11 may include one or more linear lamp. The one or more linear lamp of the lower lamp array 11 may be substantially orthogonal to the one or more linear lamp of the upper lamp array 9. In accordance with certain examples, the lower lamp array 11 may include one or more spot lamp. The one or more spot lamp may be oriented upwards towards the interior 27. The one or more spot lamp may be offset from the rotation axis 29 and oblique relative to the rotation axis 29.

The divider 13 may be seated within the interior 27 of the reaction chamber 1 and divide the interior 27 into an upper chamber 31 (relative to gravity) and a lower chamber 33. The divider 13 may have a divider aperture 35. The divider aperture 35 extends through a thickness of the divider 13 and fluidly couples the upper chamber 31 to the lower chamber 33. In certain examples, the divider 13 may be formed from an opaque material. The opaque material may have a transmissivity to electromagnetic radiation within wavelengths emitted by the upper lamp array 9 and/or the lower lamp array 11 that is lower than a transmissivity of the transparent material 21 forming the reaction chamber wall 5. Non-limiting examples of suitable opaque materials may include graphite and pyrolytic carbon materials. In accordance with certain examples, the divider 13 may be encapsulated (at least partially) with a layer, such a silicon carbide (SiC) layer.

The substrate support 4 may be configured to support the substrates 2 during the deposition of a material layer 6 of a first material onto the substrate 2. In this respect it is contemplated that the substrate support 4 be arranged within the interior 27 of the reaction chamber 1 and supported for rotation R about a rotation axis 29 relative to the reaction chamber wall 5. The substrate support 4 may be arranged within the divider aperture 35 and may be rotating within said divider aperture 35 about the rotation axis 29 relative to the reaction chamber wall 5. The substrate support 4 may be operably associated with the lift and rotate module 19. In the illustrated example the substrate support 4 may be coupled to the lift and rotate module 19 by the support member 15 and the shaft 17. The support member 15 may be arranged within the lower chamber 33 and fixed to the substrate support 4 and the shaft 17. The shaft 17 may extend through a lower wall of the reaction chamber wall 5 and be operably associated with the lift and rotate module 19. The support member 15 and/or the shaft 17 may be formed from a transparent material. Examples of suitable transparent materials include quartz.

The reaction chamber 1 may comprise multiple reaction chamber components such as for example a substrate support 4 for holding the substrate 2 in the reaction chamber 1, a reaction chamber wall 5 for forming the reaction chamber 1, an injector, e.g. the injection flange 3 or showerhead for providing gasses in the reaction chamber 1, an exhaust e.g. exhaust flange 7 for removing gas from the reaction chamber 1, or a divider 13 for dividing the reaction chamber 1. The components may be made from a base material. The base material may for example be a carbonaceous material, such as graphite.

Components within the interior 27 may be partially coated with a liner of the first material on the base material. The first material may comprise a carbide selected from the group comprising silicon carbide (SiCₓ) and tantalum carbide (TaC_{x)ALD}, where x varies between 0.4 and 1). Tantalum carbide (TaCₓ) may be deposited with tantalum halide, for example tantalum (V) chloride (TaCl₅) as a first precursor and propane (C₃H₈) as a second precursor. The components may therefore have a liner of silicon carbide (SiC) or tantalum carbide (TaCₓ).

During deposition of the material layer 6 on the substrate 2 the reaction chamber component may receive a parasitic coating of silicon carbide (SiC) as well. The parasitic coating may accumulate during multiple deposition runs on the reaction chamber component and the accumulated coating may peel off during heating—cooling cycles and part of the coating may drop on the substrates 2 when the accumulated thickness may exceed some critical value.

It may therefore be necessary to remove the parasitic coating of silicon carbide (SiCₓ) on the reaction chamber components before it reaches the critical value. Removal of this parasitic coating may be difficult since the component may be coated with a liner of the same or similar silicon carbide (SiCₓ) material while the accumulated thickness can vary greatly depending on the location of the component, or part of the component, in the reactor chamber. Any cleaning process of the component may therefore not only remove the parasitic coating but can also partially remove the silicon carbide (SiCₓ) liner. With the liner partially removed the base material may be damaged by the cleaning process which may be unwanted. It may be difficult to find a cleaning process that is selectively etching the parasitic coating of silicon carbide (SiCₓ) and not removing the liner of silicon carbide (SiCₓ) of the reaction chamber component.

To protect the reaction chamber component, it may be at least partially provided with a protective layer of a second material different than the first material on top of the liner to protect the component during an etching process. The protective layer of the second material may comprise a metal, for example a metal oxide or metal nitride or metal carbide, or an alloy of two or three of the mentioned compounds. Metals may include those categorized as transition or refractory metals while the material may consist out of a stack layers composed from more than one compound or a compound composition that may vary across the layer thickness. The protective layer of the second material may be between about 50 nanometers and 500 nanometers thick, preferably the second material may be between about 100 nanometers and 200 nanometer thick. The protective layer of the second material may have a relatively low removal or etch rate, such as a greater resistance to a dry etch and/or a wet etch than the first material, and therefore may be called an etch-stop layer.

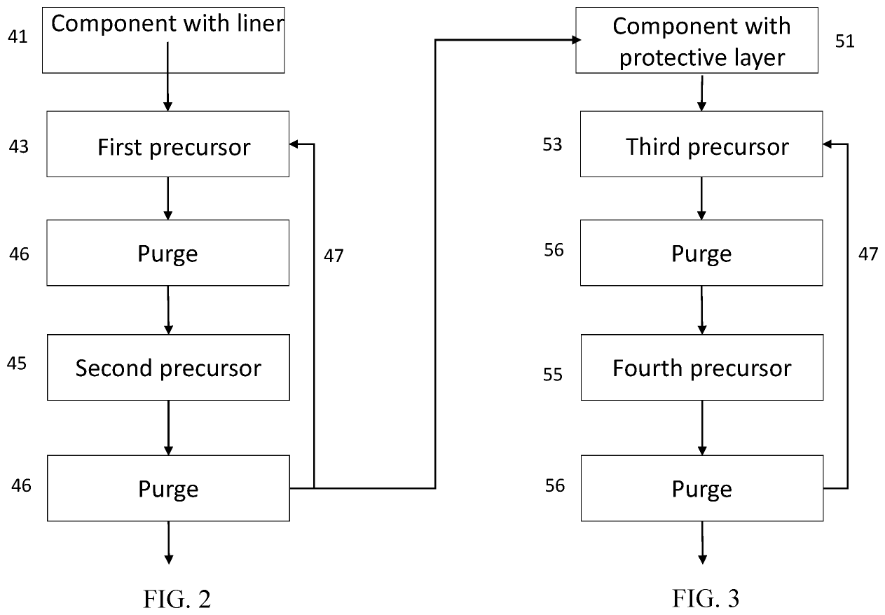

FIG. 2 is a flow chart according to an embodiment to provide the protective layer on a component according to various embodiments. The protective layer of the second material comprising a metal oxide may be created on a liner of a component 41, for example on one or more of the divider 13 and the substrate support 4 (shown in FIG. 1). The protective layer may be provided on the liner by providing a first precursor 43 comprising a metal and providing a second precursor 45 comprising oxygen to deposit metal oxide in a cyclic process. In between providing the first precursor 43 and the second precursor 45 and after providing the second precursor 45 the reaction chamber may be purged 46 in accordance with an atomic layer deposition (ALD) process. This cyclic process may be repeated 47 multiple times to create the protective layer with the required thickness.

This may be done in an apparatus for depositing layers on components or even in-situ in the apparatus as cited before for depositing layers on substrates, or a combination of both depending on effectiveness of each method. The apparatus may be provided with a precursor delivery system to provide the first and second precursor to the reaction chamber with the component. The precursor delivery system may be provided with conduits, valves heaters and control system to dose the right amount of precursor to the reaction chamber 1 (shown in FIG. 1) via, for example, the injection flange 3. The apparatus may also be provided with an exhaust, for example, exhaust flange 7 to remove precursor from the reaction chamber 1.

The protective layer may be deposited on the component with a chemical vapor deposition (CVD) process or with atomic layer deposition (ALD) process. In an atomic layer deposition (ALD) process the first and second precursors 43, 45, are provided consequentially in a cycle by the precursor delivery system. The reaction chamber 1 (shown in FIG. 1) may be purged 46 each time the first and second precursors 43, 45, have been provided. By repeating the cycle multiple times, a high-quality protective layer can be grown on the component. The protective layer may be substantially stoichiometric. The protective layer may have some degree of crystallinity. Such protective layer may exhibit a very low etch rate in a cleaning process and thus provide a high degree of protection of the liner on the component.

The metal oxide may comprise hafnium oxide (HfO₂). The hafnium oxide (HfO₂) may be deposited using a first precursor 43 comprising a metal halide such for example hafnium chloride (HfCl₄). The second precursor 45 may comprise water to deposit hafnium oxide (HfO₂) as the metal oxide on the component.

Alternatively, the protective layer may comprise silicon, for example silicon oxide (SiO₂), silicon nitride (SiN), or silicon carbon nitride (SiCN) deposited using a CVD or ALD process. The protective layer may also comprise amorphous carbon deposited using a CVD or ALD process.

The cleaning process of the component may comprise etching with any suitable etchant. The etching may be a wet etch or a dry etch. The etchant may comprise a halogen. The halogen may be fluorine (F), iodine (I), or chlorine (Cl) for example.

For a wet etch hydrofluoric acid (HF) and/or hydrochloric acid (HCl) in water may be used. Hydrofluoric acid (HF) mixed with ammonium fluoride (NH₄F), phosphoric acid (H₃PO₄), mixtures of hydrofluoric acid (HF) and nitric acid (HNO₃), mixtures of hydrofluoric acid (HF) and chromium trioxide (CrO₃), as well as mixtures of hydrofluoric acid (HF), nitric acid (HNO₃), and acetic acid (HOAc) may also be employed for the wet etch. For a wet etch the reaction chamber component has to be removed from the deposition apparatus so as to be able to provide the acidic solution to the component and remove the remnants of the parasitic coating material, ex-situ. The protective layer of the second material may protect the liner of the first material being silicon carbide (SiC), from the etchants of a wet cleaning process.

For a dry etch the etchant may be fluorine (F₂), boron trifluoride (BF₃), nitrogen trifluoride (NF₃) or chlorine trifluoride (ClF₃) for example. Dry etch chemistries including high temperature hydrochloric acid (HCl), and mixtures of tetrafluoromethane (CF₄) and oxygen (O₂) may also be employed for the dry etch. The etchant may be activated by a (remote) plasma and/or thermally activated. For a dry etch the reaction chamber component may be cleaned in the reaction chamber of the deposition apparatus by providing the etch gases to the inside of the reaction chamber in-situ.

The dry etch cleaning process of the component may be done at a temperature between about 100 degrees Celsius and about 1300 degrees Celsius, preferably between about 150 degrees Celsius and about 500 degrees Celsius to thermally activate the etchant. The cleaning process may remove silicon carbide (SiC) of the component. The protective layer of the second material may protect the liner of the first material being silicon carbide (SiC) from the etchants of a dry etch cleaning process.

The protective layer of the second material may comprise a metal oxide. The metal oxide may comprise aluminum oxide (Al₂O₃). The protective layer of aluminum oxide (Al₂O₃) may be deposited on the reaction chamber component by, in this case, providing a first precursor 43 such as trimethylaluminum (TMA) and providing a second precursor 45 such as water according to the flow chart in FIG. 2 The precursor delivery system of the deposition apparatus may be constructed and arranged to deliver trimethylaluminum (TMA) and water to the reaction chamber to deposit the aluminum oxide on the component. The protective layer of aluminum oxide may be deposited with a chemical vapor deposition (CVD) process or with an atomic layer deposition (ALD) process. For an ALD process the reaction chamber may be purged 46 each time the first and second precursors 43, 45, have been provided. This cyclic process may be repeated 47 multiple times to create the protective layer with the required thickness.

The protective layer of the second material may comprise a metal nitride. The metal nitride may comprise aluminum nitride (AlN). The protective layer of aluminum nitride (AlN) may be deposited on the reaction chamber component, in this case, by providing a first precursor 43, such as trimethylaluminum (TMA), and a second precursor 45, such as ammonia (NH₃), to deposit the aluminum nitride (AlN). The precursor delivery system of the deposition apparatus may be constructed and arranged to deliver trimethylaluminum (TMA) and ammonia (NH₃) to the reaction chamber to deposit the aluminum nitride layer on the component. The protective layer of aluminum nitride may be deposited with a chemical vapor deposition (CVD) process or with an atomic layer deposition (ALD) process. For an ALD process the reaction chamber may be purged 46 each time the first and second precursors 43, 45, have been provided. This cyclic process may be repeated 47 multiple times to create the protective layer with the required thickness. This may be done in an apparatus for depositing layers on components or even in-situ in the apparatus as cited before for depositing layers on substrates, or a combination of both depending on effectiveness of each method.

The reaction chamber component may comprise a sacrificial layer on top of the protective layer. The parasitic coating may be on top of the sacrificial layer. The sacrificial layer may have a very high etch rate in the cleaning process of the component. The parasitic coating may be undercut by etching the sacrificial layer underneath the parasitic coating. The undercut and subsequent lift-off nature of the etching process may require that the process may only take place ex-situ so that the remnants of the parasitic coating may be removed. The sacrificial layer may comprise a metal oxide. The sacrificial layer may be between 50 nanometers and about 500 nanometers, and preferably between about 100 nanometers and about 200 nanometers thick. The metal oxide may comprise aluminum oxide (Al₂O₃), such as aluminum (Al₂O₃) deposited using the ALD technique, or silicon oxide (SiO₂). Here we propose the same material for the sacrificial layer as for the etch stop layer. For the sacrificial layer a high etch rate compared to the etch rate of the parasitic coating may be beneficial, while for the etch stop layer a low etch rate compared to the etch rate of the parasitic coating may be beneficial. Differences in deposition techniques (ALD vs. CVD) or deposition temperature may be used to influence the etch rate.

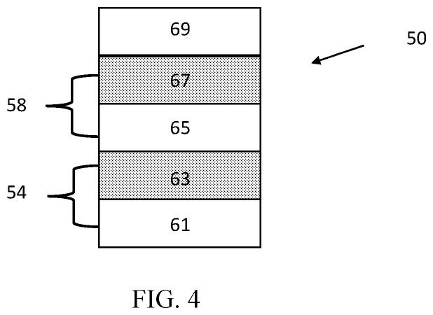

FIG. 3 is a flow chart according to an embodiment to provide a sacrificial layer on a reaction chamber component 51 (shown in FIG. 4) covered with a protective layer in accordance with FIG. 2. The sacrificial layer may be deposited by providing a third precursor 53 such as trimethylaluminum (TMA) and providing a fourth precursor 55 such as water to deposit aluminum oxide (AlO₂) on the component. The aluminum oxide (Al₂O₃) may be deposited with a chemical vapor deposition (CVD) process or with an atomic layer deposition (ALD) process. For an ALD process the reaction chamber 1 (shown in FIG. 1) may be purged 56 each time the third and fourth precursors 53, 55, have been provided. This cyclic process may be repeated 47 multiple times to create the protective layer with the required thickness. The precursor delivery system of the deposition apparatus may be constructed and arranged to deliver the third and fourth precursor 53, 55 to the reaction chamber 1 to deposit the aluminum oxide sacrificial layer on the reaction chamber component 51.

The reaction chamber component 51 (shown in FIG. 4) may be mounted in a deposition apparatus for depositing a layer of a first material on a substrate, e.g. the substrate 2 (shown in FIG. 1). The substrate 2 may be a silicon or silicon carbide wafer. The layer of the first material may for example be silicon carbide (SiC). The reaction chamber 1 may be constructed and arranged to hold the substrate 2 and to deposit a material layer e.g., the material layer 6 (shown in FIG. 1) of the first material comprising silicon carbide (SiC) on the substrate 2.

The apparatus may be constructed and arranged to provide a silicon precursor comprising silicon and providing a carbon precursor comprising carbon to the reaction chamber 1 (shown in FIG. 1) to deposit a layer of silicon carbide (SiC) on the substrate. The silicon precursor may be silane (SiH₄) or di-chlorosilane (SiCl₂H₂). The carbon precursor may be an alkene such as methane (CH₄), ethane (C₂H₆), or propane (C₃H₈).

The apparatus may be provided with a precursor delivery system to provide the silicon and carbon precursor to the reaction chamber 1 (shown in FIG. 1). This may, for example, be done by a chemical vapor deposition (CVD) process or with atomic layer deposition (ALD) process. In an atomic layer deposition (ALD) process the silicon and carbon precursors may be provided consecutively in a cycle by the precursor delivery system. The reaction chamber may be purged each time the silicon and carbon precursors have been provided. The precursor delivery system may be provided with conduits, valves heaters and control system to dose the right amount of precursor to the reaction chamber. The apparatus may also be provided with an exhaust to remove precursor from the reaction chamber.

By repeating the cycle of providing the silicon and carbon precursors consecutively in a cycle multiple times and purging in between a high-quality layer of silicon carbide (SiC) may be grown. The silicon carbide layer may be substantially stoichiometric. The silicon carbide layer may be crystalline. Such a silicon carbide layer may have a low etch rate. The silicon carbide layer may be grown on the substrate 2 (shown in FIG. 1), but it may also be grown on the reaction chamber components. Growing silicon carbide (SiC) on the reaction chamber components may be unwanted so that a cleaning process to remove it may be necessary.

FIG. 4 is a cross-sectional view of the layers on a part of the reaction chamber component 50 according to an embodiment. The reaction chamber component 50 comprises a base material 61, for example formed from silicon oxide or graphite. The base material 61 may be coated with a liner 63 of a first material, for example silicon carbide (SiC) or tantalum carbide (TaC). The manufacturer of the reaction chamber component 50 may deliver the reaction chamber component 50 with a silicon carbide (SiC) or tantalum carbide (TaCₓ, where x varies between 0.4 and 1) layer overlaying the base material 61 forming the liner 63 as a coated reaction chamber component 54.

The reaction chamber component 50 may at least partially be provided with protective layer 65 of a second material different than the first material on top of the liner 63 of the first material to protect the reaction chamber component 50 during a cleaning process, for example, by operating as an etch stop during an etching operation used to remove silicon carbide (SiC) overlaying the liner 63. For example, the silicon carbide layer may be removed with a wet etch or a dry etch, and the protective layer 65 may protect the liner 63 from the wet etch or the dry etch during the wet etch or the dry etch. The protective layer 65 may be substantially stoichiometric. The protective layer 65 may be crystalline. The protective layer may have a low etch rate compared to the etch rate of the parasitic coating.

The protective layer 65 may comprise metal oxide and may comprise hafnium oxide (HfO₂) or aluminum oxide (Al₂O₃). The protective layer 65 may comprise metal nitride. The metal nitride may comprise aluminum nitride (AlN). In certain examples, the reaction chamber component 50 may include a tantalum carbide (TaC) forming the liner 63 only, the parasitic coating 69 being deposited directly onto the linear 63.

The protective layer of the second material may be between about 50 nanometers and 500 nanometers thick, preferably the second material may be between about 100 nanometers and 200 nanometer thick. Such protective layer may give a high etch resistance to a component in a cleaning process.

Alternatively, the protective layer 65 may comprise a metal carbide. The metal carbide may be different than silicon carbide. The metal carbide may be deposited using a metal halide as the precursor.

For example, the protective layer 60 may comprise tantalum carbide (TaCₓ, where x varies between 0.4 and 1). Tantalum carbide may be deposited with tantalum halide, for example tantalum (V) chloride (TaCl₅) as a first precursor and propane (C₃H₈) as a second precursor.

The reaction chamber component 50 may at least partially be provided with an optional sacrificial layer 67 on top of (e.g. overlaying) the protective layer 65. The sacrificial layer 67 may have a relatively high etch rate compared to the etch rate of the protective layer 65. The sacrificial layer 67 may comprise a metal oxide. The metal oxide may comprise aluminum oxide (Al₂O₃). The protective layer 65 and the sacrificial layer 67 may be produced with a chemical vapor deposition (CVD) process or an atomic layer deposition ALD process and may be defined as deposition layers 56. Advantageously, the protective layer 65 may be produced with an atomic layer deposition ALD process to decrease the etch rate of the protective layer while the sacrificial layer 67 may be produced with a chemical vapor deposition (CVD) to increase the deposition speed while the etch rate may be increased because it is less critical.

During use of the reaction chamber component 50 in a reaction chamber for a deposition apparatus for depositing a layer of a first material (e.g. silicon carbide) on a substrate, e.g., the substrate 2 (shown FIG. 1), the reaction chamber component 50 may become (at least partially) coated with a parasitic coating 59 of silicon carbide (SiC). This parasitic coating 69 and the optional sacrificial layer 67 may be removed in a subsequent cleaning process. The cleaning process may be in-situ or ex-situ. The ex-situ cleaning process may be preferred when using a sacrificial layer since larger flakes can be more easily flushed away in an ex situ cleaning process. The sacrificial layer 67 may have an etch rate higher than that of the parasitic coating 69. The removal of the sacrificial layer 67 may therefore be quicker than that of the parasitic coating 69. In this way the parasitic coating 69 may be released by lift-off and subsequently removed from the component.

The protective layer 65 of the reaction chamber component 50 may comprise a telltale layer comprising a telltale metal. The apparatus may comprise a sensor for detecting the presence of the telltale metal in the exhaust during a cleaning e.g. etching process of the reaction chamber component 50. The presence of the telltale metal in the exhaust may be indicative of a progress of the etching process. If the presence of the telltale metal in the exhaust reaches a certain threshold value one may stop the etching process to circumvent over etching of the reaction chamber component 50.

The telltale metal of the protective layer 65 may be different than silicon. The telltale metal may comprise a metal carbide. The telltale metal may comprise a metal nitride. Metal carbide and metal nitride may have reaction products when etched away which may be very different from those of silicon carbide when it comes to mass or absorption/emission spectra. The metal compound may be selected to be highly volatile, has an atomic mass very different from those found in the protective layer 65, the sacrificial layer 67 and the parasitic coating 69. The telltale metal should be selected such that it may be deposited on or in the protective layer 65, preferably even in the same reactor. The telltale metal may be thermally and chemically stable at the deposition temperature, and has an etch rate less than 3×, preferably less than 10× and more preferably less than 30× of the parasitic coating 69. Inevitably some of the telltale metal may be etched during the cleaning step. In between substrates, or in between multiple substrates, a recovery deposition of the telltale metal can be made to assure it protects all the relevant surfaces in the reactor from the cleaning chemistry.

The metal carbide may be tantalum carbide (TaCₓ, where x varies between 0.4 and 1). Tantalum carbide may be deposited with tantalum halide, for example tantalum (V) chloride (TaCl₅) as a first precursor and propane (C₃H₈) as a second precursor.

The illustrations presented herein are not meant to be actual views of any particular material, structure, or device, but are merely idealized representations that are used to describe embodiments of the disclosure.

The implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and sub-combinations of the various processes, systems, and configurations, and other features, functions, acts, and/or properties disclosed herein, as well as any and all equivalents thereof.

1. A reaction chamber component for a reaction chamber for a deposition apparatus for depositing a layer of a first material on a substrate, the component comprising a base material being at least partially coated with a liner of the first material, wherein the component is at least partially provided with a protective layer of a second material different than the first material on top of the liner of the first material to protect the component.

2. The component according to claim 1, wherein the protective layer of the second material comprises a metal oxide.

3. The component according to claim 2, wherein the metal oxide comprises hafnium oxide (HfO₂).

4. The component according to claim 2, wherein the metal oxide comprises aluminum oxide (Al₂O₃).

5. The component according to claim 1, wherein the protective layer of the second material comprises a metal nitride.

6. The component according to claim 5, wherein the metal nitride comprises aluminum nitride (AlN).

7. The component according to claim 1, further comprising a sacrificial layer on top of the protective top layer.

8. The component according to claim 7, wherein the sacrificial layer comprises a metal oxide.

9. The component according to claim 8, wherein the metal oxide comprises aluminum oxide (Al₂O₃).

10. The component according to claim 1, wherein the first material of the liner comprises a carbide selected from the group comprising silicon carbide (SiC) and tantalum carbide (TaC).

11. The component according to claim 1, wherein the base material comprises graphite.

12. The component according to claim 1, wherein the component is a substrate support assembly for holding a substrate in the reaction chamber, a reaction chamber wall for forming the reaction chamber, a divider assembly for dividing the reaction chamber, an injector assembly for providing gasses in the reaction chamber, or an exhaust assembly for removing gas from the reaction chamber.

13. The component according to claim 1, wherein the protective layer is provided with a silicon carbide (SiC) layer on top.

14. The component according to claim 7, wherein the sacrificial layer is provided with a silicon carbide (SiC) layer on top.

15. The component according to claim 1, wherein the protective layer comprises a metal carbide, different than silicon carbide (SiC), preferably tantalum carbide (TaC).

16. The component according to claim 1, wherein the protective layer comprises a telltale layer comprising a telltale metal to signal a progress of a cleaning process of the component.

17. A deposition apparatus for depositing a layer of a first material being silicon carbide on a substrate, wherein the apparatus comprises the component according to claim 1.

18. The apparatus according to claim 17, wherein the protective layer provided to the component comprises a telltale layer comprising a telltale metal and the apparatus comprises a sensor for detecting the presentence of the telltale metal in the exhaust during a cleaning process of the component indicative of a progress of the cleaning process.

19. A method of protecting a reaction chamber component for a reaction chamber of an apparatus for depositing a layer of a first material on a substrate and the component being at least partially coated with a liner of the first material, the method comprising providing a protective layer of a second material different than the first material on top of the liner of the first material.

20. The method according to claim 19, wherein providing a protective layer of the second material comprises providing a metal oxide by providing a first precursor comprising a metal and providing a second precursor comprising oxygen to deposit metal oxide as the second material.

21. The method according to claim 20, wherein providing the first precursor comprises providing a metal halide such as hafnium chloride (HfCl₄) and providing the second precursor comprises providing water to deposit hafnium oxide (HfO₂) as the metal oxide.

22. The method according to claim 20, wherein providing a protective top layer of the second material comprises providing a first precursor such as trimethylaluminum (TMA) and providing a second precursor such as water to deposit aluminum oxide (Al₂O₃).

23. The method according to claim 19, wherein providing a protective top layer of a second material comprises providing a metal nitride.

24. The method according to claim 23, wherein providing a protective top layer of a second material comprises providing a first precursor, such as trimethylaluminum (TMA), and a second precursor, such as ammonia (NH₃), to deposit aluminum nitride (AlN).

25. The method according to claim 21, wherein the method comprises providing a sacrificial layer on top of the protective top layer.

26. The method according to claim 25, wherein the method comprises providing a silicon carbide layer on top of the sacrificial layer.

27. The method according to claim 19, wherein the method comprises providing a silicon carbide layer on top of the protective layer.

28. The method according to claim 27, wherein the method comprises removing the silicon carbide layer with a wet etch or a dry etch and protecting the liner from the wet etch or the dry etch with the protective layer during the wet etch or the dry etch.
